(19) United States
(12) Patent Application Publication
(10) Pub. No.: US 2013/0118794 A1
(43) Pub. Date: May 16, 2013

(54) Package Substrate Structure

(71) Applicant: Bo-Yu Tseng, Hsinchu (TW)

(72) Inventor: Bo-Yu Tseng, Hsinchu (TW)

(21) Appl. No.: 13/297,257

(22) Filed: Nov. 15, 2011

(51) Int. Cl. H05K 1/11

(52) U.S. Cl. 174/266

(57) ABSTRACT

A package substrate structure includes a substrate, a circuit layer formed on the substrate, and an ultra-thin seed layer made of an electrically conductive material and formed between the substrate and the circuit layer. The ultra-thin seed layer is advantageous to increase the adhesion between the metal bumps or the circuit lines of the circuit layer, and the substrate. Furthermore, because the seed layer is ultra thin, the metal bumps or the circuit lines on the package substrate can be made finer in line widths and line pitches, and the good yield of the substrate with fine circuit lines can be increased.

### BACKGROUND OF THE INVENTION

1. Field of the Invention

The present invention relates to a package substrate structure, and more particularly to a package substrate structure having an ultra-thin seed layer for increasing the adhesion between the package substrate and the metal bumps or the circuit lines. Accordingly, the metal bumps or the circuit lines on the package substrate can be made finer in line widths and line pitches because the seed layer is ultra thin.

2. The Prior Arts

In a conventional package substrate structure, a copper foil is directly bonded to the surface of the substrate as a conductive layer, and followed by photolithography, plating and etching to form the circuits, and the thickness of the copper foil is generally between 3 to 12 μm. Recently, the printed circuit boards are developed toward lightweight, thin, short and small size, and high density. Therefore, the demand for finer metal line widths and line pitches is increasing day by day.

If the wiring density of the circuit is high, the metal line widths and metal line pitches need to become smaller. However, the thickness of the copper foil, which is conventionally served as a conductive layer, is between 3 to 12 μm so that the shortening of metal line pitches is restricted, and thereby the wiring density and the good yield of the substrate with fine circuit lines cannot be increased. Moreover, the reduction in size of the circuit lines brought about a decrease in the adhesion between the substrate and the circuit lines, and thereby the circuit lines and the substrate are easily separated from each other.

Therefore, there is a need for providing a package substrate structure that can enhance the adhesion between the package substrate and the circuit lines, and can reduce the line width and line pitch of the circuit lines. Therefore, the good yield of the fine circuit lines can be increased.

### SUMMARY OF THE INVENTION

An objective of the present invention is to provide a package substrate structure which can be a monolayer, double-layer or multiple-layer structure, and the package substrate structure comprises a substrate, at least one via hole, a circuit layer having a plurality of metal bumps, and an ultra-thin seed layer. The ultra-thin seed layer made of electrically conductive material is formed between the substrate surface of the substrate and the metal bumps, and between the sidewall of the at least one via hole and metallic material filled in the at least one via hole. The ultra-thin seed layer is advantageous to increase the adhesion between the metal bumps or the circuit lines, and the substrate. Moreover, because the seed layer is ultra thin, the metal bumps or the circuit lines on the package substrate can be made finer in line widths and line pitches, and the good yield of the substrate with fine circuit lines can be increased.

The present invention will become more obvious from the following description when taken in connection with the accompanying drawings which show, for purposes of illustration only, a preferred embodiment in accordance with the present invention.

### BRIEF DESCRIPTION OF THE DRAWINGS

The present invention will become more apparent by describing embodiments thereof in detail with reference to the accompanying drawing in which:

FIG. 1 is a cross-sectional view showing a package substrate structure according to a first embodiment of the present invention;

FIG. 2 is a cross-sectional view showing a package substrate structure according to a second embodiment of the present invention; and

FIG. 3 is a cross-sectional view showing a package substrate structure according to a third embodiment of the present invention.

### DETAILED DESCRIPTION OF THE PREFERRED EMBODIMENTS

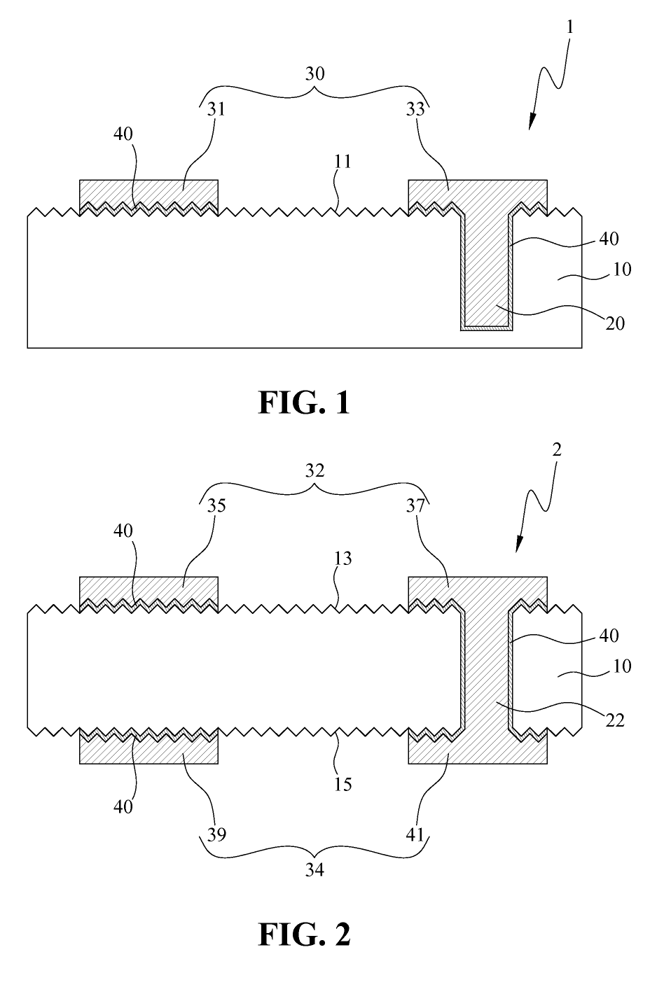

Referring to FIG. 1, a monolayer package substrate structure 1 according to the present invention comprises a substrate 10, an ultra thin seed layer 40, and a circuit layer 30. The substrate 10 has a substrate surface 11, and has at least one via hole 20 is formed therein. The ultra thin seed layer 40 is made of electrically conductive material, and is formed on portions of the substrate surface and on a sidewall and a bottom of the at least one via hole 20. The circuit layer 30 includes a plurality of metal bumps 31 and 33 wherein the metal bump 31 is formed on the ultra thin seed layer 40 formed on the portions of the substrate surface 11, and the metal bump 33 is formed on the at least one via hole 20 filled with a metallic material. In this embodiment, the ultra thin seed layer 40 is formed between the substrate surface 11 and the plurality of metal bumps 31 and 33, and also formed between the sidewall and the bottom of the at least one via hole 20, and the metallic material filled in the at least one via hole 20.

The at least one via hole 20 comprises at least one of a blind via hole, a buried via hole, and a through hole. The metal bumps 31 and 33 are made of copper or copper alloy. The substrate surface 11 is rough. The ultra thin seed layer 40 is formed along the substrate surface 11, and the thickness of the ultra thin seed layer 40 is less than 1 μm, and the ultra thin seed layer 40 is used to increase the adhesion between the substrate 10 and the metal bumps 31 and 33. The substrate 10 has an upper substrate surface 11 and a lower substrate surface 11. In this embodiment, only the upper substrate surface 11 is used.

Please refer to FIG. 2, which shows the second embodiment of the present invention. In the second embodiment, the package substrate structure 2 is a double-layer package substrate structure. The package substrate structure 2 comprises a substrate 10, an ultra thin seed layer 40, an upper circuit layer 32, and a lower circuit layer 34. The substrate 10 has an upper substrate surface 13 and a lower substrate surface 15, and has at least one via hole 22 formed therein. The ultra thin seed layer 40 is made of electrically conductive material, and the ultra thin seed layer 40 is formed on portions of the upper substrate surface 13 and portions of the lower substrate surface 15, and also on the sidewall of the at least one via hole 22. The upper circuit layer 32 includes a plurality of metal bumps 35 and 37 wherein the metal bump 35 is formed on the ultra thin seed layer 40 formed on the portions of the upper substrate surface 13, and the metal bump 37 is formed on one end of the at least one via hole 22 filled with a metallic material. The lower circuit layer 34 includes a plurality of metal bumps 39 and 41, wherein the metal bump 39 is formed on the ultra thin seed layer 40 formed on the portions of the lower substrate surface 15, and the metal bump 41 is formed on another end of the at least one via hole 22 filled with the metallic material. In this embodiment, the ultra thin seed layer 40 is formed between the upper substrate surface 13 and the metal bumps 35 and 37, and formed between the lower substrate surface 15 and the metal bumps 39 and 41, and the ultra thin seed layer 40 is also formed between the sidewall of the at least one via hole 22 and the metallic material filled in the at least one via hole 22, and the upper and lower circuit layers 32 and 34 are electrically connected with each other through the metallic material filled in the through hole 22.

The at least one via hole 22 comprises at least one of a blind via hole, a buried via hole, and a through hole. The metal bumps 35, 37, 39, and 41 are made of copper or copper alloy. The upper and lower substrate surface 13 and 15 are rough. The ultra thin seed layer 40 is formed along the upper and lower substrate surfaces 13 and 15, and the thickness of the ultra thin seed layer 40 is less than 1 μm, and the ultra thin seed layer 40 is used to increase the adhesion between the substrate 10 and the metal bumps 35, 37, 39, and 41.

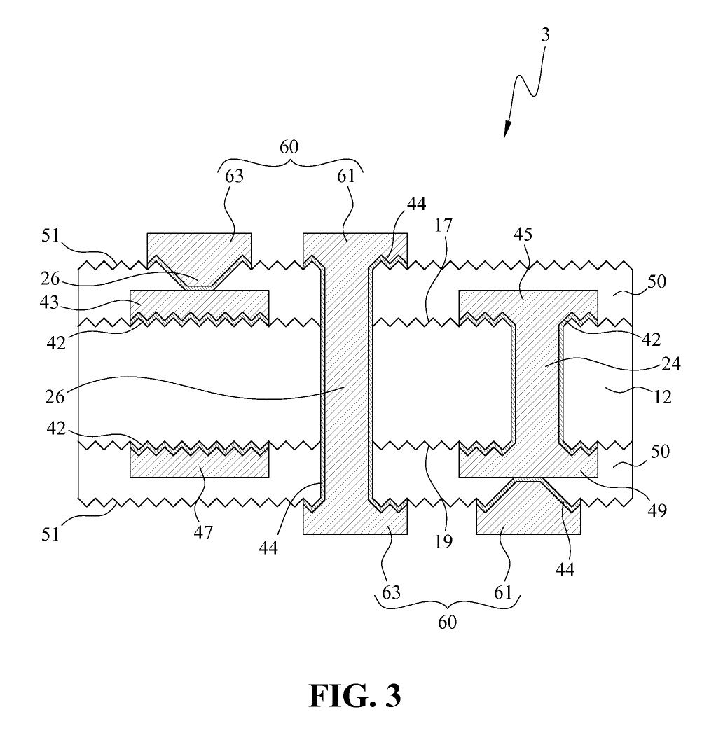

Please refer to FIG. 3, which shows the third embodiment of the present invention. In the third embodiment, the package substrate structure 3 is a multiple-layer package substrate structure. The package substrate structure 3 comprises a first substrate 12, an ultra thin first seed layer 42, a first circuit layer, a second circuit layer, at least one second substrate 50, an ultra thin second seed layer 44, and at least one external circuit layer 60. The first substrate 12 has a first substrate surface 17 and a second substrate surface 19, and the first substrate 12 has at least one first via hole 24 formed therein. The ultra thin first seed layer 42 is made of electrically conductive material, and is formed on portions of the first substrate surface 17, portions of the second substrate surface 19, and a sidewall of the at least one first via hole 24. The first circuit layer has a plurality of metal bumps 43 and 45, wherein the metal bump 43 is formed on the ultra thin first seed layer 42 formed on the portions of the first substrate surface 17, and the metal bump 45 is formed on one end of the at least one first via hole 24 filled with a metallic material. The second circuit layer has a plurality of metal bumps 47 and 49, wherein the metal bump 47 is formed on the ultra thin first seed layer 42 formed on the portions of the second substrate surface 19, and the metal bump 49 is formed on another end of the at least one first via hole 24 filled with a metallic material. At least one second substrate 50 is stacked on the first substrate surface 17, the first circuit layer, and/or stacked on the second substrate surface 19 and the second circuit layer. The at least one second substrate has the outer substrate surfaces 51, and has at least one second via hole 26 formed therein. The ultra thin second seed layer 44 is made of electrically conductive material, and formed on portions of the outer substrate surfaces 51 and a sidewall of the at least one second via hole 26. At least one external circuit layer 60 includes a plurality of metal bumps 61 and 63, wherein the metal bump 63 is formed on the ultra thin second seed layer 44 formed on the portions of the outer substrate surfaces 51, and the metal bump 61 is formed on at least one end of the at least one second via hole 26 filled with a metallic material. In this embodiment, the ultra thin first seed layer 42 is formed between the first substrate surface 17 and the metal bumps 43 and 45, and is formed between the second substrate surface 19 and the metal bumps 47 and 49, and the ultra thin first seed layer 42 is also formed between the sidewall of the at least one first via hole 24 and the metallic material which is filled in the at least one first via hole 24. The ultra thin second seed layer 44 is formed between the outer substrate surface 51 and the metal bumps 61 and 63, and the ultra thin second seed layer 44 is also formed between the sidewall of the at least one second via hole 26 and the metallic material which is filled in the at least one second via hole 26. The first and second circuit layers are electrically connected with each other through the metallic material filled in the via hole.

In the third embodiment, the at least first via hole 24 and the at least second via hole 26 comprise at least one of a blind via hole, a buried via hole, and a through hole. The metal bumps 43, 45, 47, 49, 61 and 63 are made of copper or copper alloy. The first and second substrate surfaces 17 and 19 and the outer substrate surfaces 51 are rough, and the ultra thin first seed layer 42 is formed along the first and the second substrate surfaces 17 and 19, and the ultra thin second seed layer 44 is formed along the outer surfaces 51. The thickness of the ultra thin first and second seed layer 42 and 44 are less than 1 μm.

The ultra-thin seed layer is advantageous to increase the adhesion between the metal bumps or the circuit lines and the substrate. In the present invention, the metal bumps or the circuit lines which are to be formed on the package substrate can be made finer in line widths and line pitches, and the good yield of the substrate with fine circuit lines can be increased.

While we have shown and described the embodiment in accordance with the present invention, it should be clear to those skilled in the art that further embodiments may be made without departing from the scope of the present invention.

What is claimed is:

1. A package substrate structure comprising:
a substrate having a substrate surface and having at least one via hole formed therein;
a seed layer made of electrically conductive material and formed on portions of the substrate surface, and on a sidewall and a bottom of the at least one via hole; and
a circuit layer including a plurality of metal bumps formed on the seed layer formed on the portions of the substrate surface, and also formed on the at least one via hole filled with a metallic material,
wherein the seed layer is formed between the substrate surface and the metal bumps, and also formed between the sidewall and the bottom of the at least one via hole, and the metallic material filled in the at least one via hole.

2. The package substrate structure as claimed in claim 1, wherein a thickness of the seed layer is less than 1 μm.

3. The package substrate structure as claimed in claim 1, wherein the at least one via hole comprises at least one of a blind via hole, a buried via hole, and a through hole.

4. The package substrate structure as claimed in claim 1, wherein the substrate surface is rough, and the seed layer is formed along the substrate surface.

5. A package substrate structure comprising:
a substrate having an upper substrate surface and a lower substrate surface and having at least one via hole formed therein;
a seed layer made of electrically conductive material and formed on portions of the upper substrate surface and portions of the lower substrate surface, and a sidewall of the at least one via hole;
an upper circuit layer including a plurality of metal bumps formed on the seed layer formed on the portions of the upper substrate surface, and formed on one end of the at least one via hole filled with a metallic material;
a lower circuit layer including a plurality of metal bumps formed on the seed layer formed on the portions of the lower substrate surface, and formed on another end of the at least one via hole filled with the metallic material,
wherein the seed layer is formed between the upper substrate surface and the metal bumps and between the lower substrate surface and the metal bumps, and also formed between the sidewall of the at least one via hole and the metallic material filled in the at least one via hole, and
the upper and lower circuit layers are electrically connected with each other through the metallic material filled in the through hole.

6. The package substrate structure as claimed in claim 5, wherein a thickness of the seed layer is less than 1 μm.

7. The package substrate structure as claimed in claim 5, wherein the at least one via hole comprises at least one of a blind via hole, a buried via hole, and a through hole.

8. The package substrate structure as claimed in claim 5, wherein the substrate surface is rough, and the seed layer is formed along the upper and lower substrate surfaces.

9. A package substrate structure comprising:
a first substrate having a first substrate surface and a second substrate surface, and having at least one first via hole formed therein;
a first seed layer made of electrically conductive material, and formed on portions of the first substrate surface and portions of the second substrate surface, and a sidewall of the at least one first via hole;
a first circuit layer having a plurality of metal bumps formed on the first seed layer formed on the portions of the first substrate surface, and formed on one end of the at least one first via hole filled with a metallic material;
a second circuit layer having a plurality of metal bumps formed on the first seed layer formed on the portions of the second substrate surface, and formed on another end of the at least one first via hole filled with a metallic material;
at least one second substrate stacked on the first substrate surface and the first circuit layer, and/or stacked on the second substrate surface and the second circuit layer, the at least one second substrate having outer substrate surfaces, and having at least one second via hole formed therein;
a second seed layer made of electrically conductive material, and formed on portions of the outer substrate surfaces and a sidewall of the at least one second via hole; and
at least one external circuit layer having a plurality of metal bumps formed on the second seed layer formed on the portions of the outer substrate surfaces, and formed on at least one end of the at least one second via hole filled with a metallic material,
wherein the first seed layer is formed between the first substrate surface and the metal bumps, and is formed between the second substrate surface and the metal bumps, and the first seed layer is also formed between the sidewall of the at least one first via hole and the metallic material filled in the at least one first via hole, and the second seed layer is formed between the outer substrate surfaces and the metal bumps, and the second seed layer is also formed between the sidewall of the at least one second via hole and the metallic material which is filled in the at least one second via hole, and
the first and second circuit layers are electrically connected with each other through the metallic material filled in the through hole.

10. The package substrate structure as claimed in claim 9, wherein the at least one second via hole is a through hole extending through the first and second substrates, and when the through hole is filled, the exterior circuit layers located on the two opposite outer substrate surfaces of the second substrates are electrically connected to each other.

11. The package substrate structure as claimed in claim 9, wherein a thickness of the first seed layer and a thickness of the second seed layer are less than 1 μm.

12. The package substrate structure as claimed in claim 9, wherein the at least first via hole and the at least second via hole comprise at least one of a blind via hole, a buried via hole, and a through hole.

13. The package substrate structure as claimed in claim 9, wherein the first and second substrate surfaces and the outer substrate surfaces are rough, and the first seed layer is formed along the first and the second substrate surfaces, and the second seed layer is formed along the outer surfaces.
